(19) United States
(12) Patent Application Publication
(10) Pub. No.: US 2020/0098943 A1
(43) Pub. Date: Mar. 26, 2020

(54) SOLAR CELL MODULE AND MANUFACTURING METHOD THEREOF

(71) Applicant: KANEKA CORPORATION, Osaka--shi, Osaka (JP)

(72) Inventors: Toru TERASHITA, Settsu-shi (JP); Gensuke KOIZUMI, Settsu-shi (JP)

(21) Appl. No.: 16/495,509

(22) PCT Filed: Mar. 22, 2018
(86) PCT No.: PCT/JP2018/011512

§ 371 Date: Sep. 19, 2019

(30) Foreign Application Priority Data
Mar. 28, 2017 (JP) 2017-063968

(51) Int. Cl. H01L 31/05; H01L 31/0224

(52) U.S. Cl. CPC H01L 31/0508; H01L 31/022441; H01L 31/0516

(57) ABSTRACT

Disclosed herein is a solar cell module including a plurality of solar cells having metal electrodes. The solar cell module further includes a wiring member connecting the plurality of solar cells via the metal electrodes. Also disclosed herein is a method of producing the solar cell module.

### PRIORITY CLAIM AND CROSS-REFERENCE

The instant Application is a US National Phase Application of the PCT Application PCT/JP2018/011512 dated Mar. 22, 2018, which claims priority from Japanese Application No. 2017-0063968 dated Mar. 28, 2017. The entireties of both documents are hereby incorporated herein by reference.

### BACKGROUND

Solar cells that include crystalline semiconductor substrates such as a single-crystalline silicon substrate and a polycrystalline silicon substrate have a small area for one substrate, and thus in practical use, a plurality of solar cells are electrically connected and modularized for increasing output. In the case of a double-sided electrode type solar cell having electrodes on a light-receiving surface and a back surface, a plurality of solar cells are connected in series by electrically connecting a light-receiving surface electrode of one of two adjacent solar cells to a back electrode of the other solar cell. In the case of a back contact solar cell having an electrode only on a back surface, a plurality of solar cells are connected in series by electrically connecting an n-side electrode of one solar cell to a p-type electrode of the other solar cell.

A wiring member is used for electrical connection of the electrodes of adjacent solar cells. In general, a flat square belt-shaped metal wire covered with solder is used as the wiring member. JP H11-177117 A and JP 2005-353549 A suggest that a braided wire obtained by bundling a plurality of metal element wires is used as the wiring member, and is solder-connected to a metal electrode of a solar cell.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic sectional view of a solar cell module according to some embodiments.

FIG. 2 is a plan view of a back surface of a solar cell grid according to some embodiments.

FIG. 3 is a schematic perspective view of a solar cell string according to some embodiments.

FIG. 4 is a cross-sectional image of a connection portion between a solar cell and a wiring member according to some embodiments.

FIG. 5 is a cross-sectional image of a connection portion between a solar cell and a wiring member according to some embodiments.

FIG. 6 is a cross-sectional image of a connection portion between a solar cell and a wiring member according to some embodiments.

FIG. 7 is a microscope photograph of a cell surface after a peeling test for a sample heated after bonding of a wiring member according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The braided wire has high stretchability and flexibility. Therefore, in a solar cell module using a braided wire as a wiring member, stress on a connection portion, which is caused by a temperature change, is reduced to contribute to the improvement of the durability. However, studies by the present inventors have revealed that when braided wire as a wiring member is solder-connected to a metal electrode of a solar cell, there is smaller bonding strength between the wiring member and the metal electrode, so that the wiring member is more easily peeled off from the metal electrode in a temperature cycle test of a solar cell module as compared to a case where a flat (rectangular) wiring member is used.

The instant specification describes a solar cell module in which delamination between a solar cell and a wiring member due to a temperature change is suppressed. In the solar cell module, stress on a connection portion between the solar cell and the wiring member hardly occurs, and high reliability against a temperature change is exhibited. The instant specification further describes a method of manufacturing the solar cell module.

In some embodiments, the instant specification is directed to a solar cell module including a solar cell string in which a plurality of solar cells is electrically connected by a wiring member. The wiring member is a braided wire consisting of a plurality of metal element wires and having a flat-shaped cross-section. The metal electrode of the solar cell is solder-connected to the wiring member. The solar cell is solder-connected to the wiring member by, for example, allowing a solder material to permeate from the outer periphery of the braided wire to voids formed between metal element wires. Preferably, voids between a plurality of metal element wires that constitute the braided wire are filled with a solder material.

In some embodiments, the solar cell is a double-sided electrode type solar cell or a back contact solar cell. In particular, when the solar cell is a solar cell module including a back contact solar cell, the effect of improving reliability against a temperature change tends to be remarkable.

In some embodiments, the braided wire include plain-knitted wires obtained by knitting a plurality of bundled wires in which a plurality of metal element wires is bundled. In some embodiments, the plain-knitted wire includes 10 or less element wires in one bundled. In some embodiments, the metal element wire is composed of copper or copper alloy. In some embodiments, the metal element wire is subjected to a coating treatment or a surface treatment by plating or the like. In some embodiments, when the metal electrode of the solar cell is a silver electrode, the metal element wire of the braided wire is a copper wire covered with silver.

In some embodiments, in the solar cell module, the area ratio of a region filled with a solder material to a cross-section of the wiring member is preferably 10 to 90%. In some embodiments, in the cross-section of the wiring member, the area ratio of voids which have no metal element wire, and are not filled with the solder material is preferably 30% or less.

According to the embodiments, the solar cell module is excellent in temperature cycle durability because the wiring member connecting solar cells has flexibility, and bonding strength between the electrode of the solar cell and the wiring member is high.

### Solar Cell Module

In some embodiments, the instant specification is directed to a solar cell module.

In some embodiments, the solar cell module includes at least one solar cell string in which a plurality of solar cells are electrically connected by at least one wiring member.

In some embodiments, the solar cells include at least one metal electrode on a light-receiving surface or a back surface of the solar cells.

In some embodiments, the wiring member is a braided wire. In some embodiments, the braided wire has a flat-shaped cross-section and is formed of a plurality of metal element wires.

In some embodiments, the metal electrode of the solar cell is connected to the wiring member by solder.

In some embodiments, voids between the plurality of metal element wires that constitute the braided wire are filled with a solder material.

In some embodiments, in a cross-section of the wiring member, a ratio of an area filled with the solder material ranges from 10% to 90% based on a total area of the cross-section.

In some embodiments, in a cross-section of the wiring member, a ratio of a void area where neither metal element wire nor solder material presents is 30% or less based on a total area of the cross-section.

In some embodiments, the wiring member is a plain-knitted wire in which a plurality of bundles of metal element wires are knitted.

In some embodiments, a number of element wires present in one bundled wire in the plain-knitted wire is 10 or less.

In some embodiments, the metal element wire is composed of copper or a copper alloy.

In some embodiments, the metal element wire includes a metal wire composed of copper or copper alloy, and a coating layer on a surface of the metal wire. In some embodiments, the coating layer includes silver or tin.

In some embodiments, the metal element wire has a silver-coating layer on a surface of a metal wire composed of copper or a copper alloy, and the metal electrode of the solar cell is a silver electrode.

In some embodiments, the solar cell is a back contact solar cell having no metal electrode on the light-receiving surface and having metal electrodes only on the back surface, and in the solar cell string, back surfaces of adjacent solar cells are connected to each other through the wiring member.

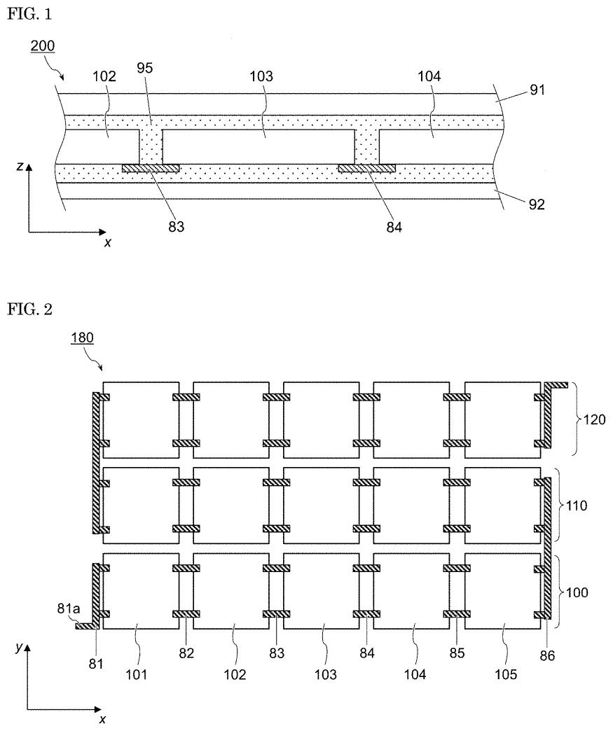

FIG. 1 is a schematic sectional view of a solar cell module (also referred to as a “module”) according to some embodiments.

Referring to FIG. 1, a module 200 includes a solar cell string in which plurality of solar cells (hereinafter referred to as “cells”) 102, 103 and 104 are electrically connected through wiring members 83 and 84.

In the module shown in FIG. 1, a back contact solar cell (also referred to as a “back contact cell”) is exemplified. The back contact cell has a p-type semiconductor layer and an n-type semiconductor layer on the back side of a semiconductor substrate of crystalline silicon or the like. The back contact cell does not have a metal electrode on the light-receiving surface of the semiconductor substrate, and photocarriers (holes and electrons) generated in the semiconductor substrate are collected by p-side electrode disposed on p-type semiconductor layer and n-side electrodes disposed on n-type semiconductor layer.

In some embodiments, the metal electrode is formed by printing or plating. In some embodiments, the metal electrode is an Ag electrode formed by screen printing of an Ag paste, a copper-plated electrode formed by electroplating, or the like. According to some embodiments, since the back contact cell does not have a metal electrode on the light-receiving surface, the entire surface of the cell is uniformly colored black when the cell is viewed from the light-receiving side.

In some embodiments, the cells in the module is a double-sided electrode type cell having a metal electrode on each of a light-receiving surface and a back surface. In some embodiments, the solar cells have a rectangular shape in plain view. As used herein, the term “rectangular shape” includes a square shape and an oblong shape. The “rectangular shape” is not required to be a perfectly square shape or oblong shape, and for example, the semiconductor substrate somethings have a semi-square shape (a rectangular shape having rounded corners, or a shape having a notched portion). In some embodiments, the cells are in a non-rectangular shape.

In some embodiments, the light-receiving surface of the cell has a recessed and projected structure for improving conversion efficiency by increasing the amount of light captured in the semiconductor substrate. In some embodiments, the shape of the projection is a quadrangular pyramidal shape. In some embodiments, the quadrangular pyramid-shaped projections are formed by, for example, subjecting a surface of the single-crystalline silicon substrate to anisotropic etching treatment. In some embodiments, a height of the projection on the light-receiving surface of the cell ranges from about 0.5 μm to about 10 μm. In some embodiments, the height of the projection ranges from about 1 μm to about 5 μm. In some embodiments, the back surface of the cell also has a recessed and projected structure.

FIG. 2 is plain view of a back surface of a solar cell grid according to some embodiments, in which a plurality of back contact cells are arranged in a grid shape.

Referring to FIG. 2, in a solar cell grid 180, solar cell strings 100, 110, and 120, in which a plurality of back contact cells are connected along a first direction (x direction), are arranged side by side along a second direction (y direction) orthogonal to the first direction.

The solar cell string 100 includes a plurality of cells 101 to 105 arranged in the first direction. Electrodes disposed on the back side of cells are electrically connected through wiring members 82 to 85 to form a solar cell string. In some embodiments, a plurality of cells is connected in series by connecting the p-side electrode of one of two adjacent cells to the n-side electrode of the other cell through the wiring member. In some embodiments, the cells are connected in parallel by connecting n-side electrodes of adjacent cells or by connecting p-side electrodes of adjacent cells.

In the solar cell string 100, the wiring member 81 arranged at one end portion in the first direction includes a lead wire 81a. In some embodiments, the lead wire 81a is connected to an external circuit. The wiring member 86 arranged at the other end portion in the first direction is connected to the solar cell string 110 adjacent in the second direction.

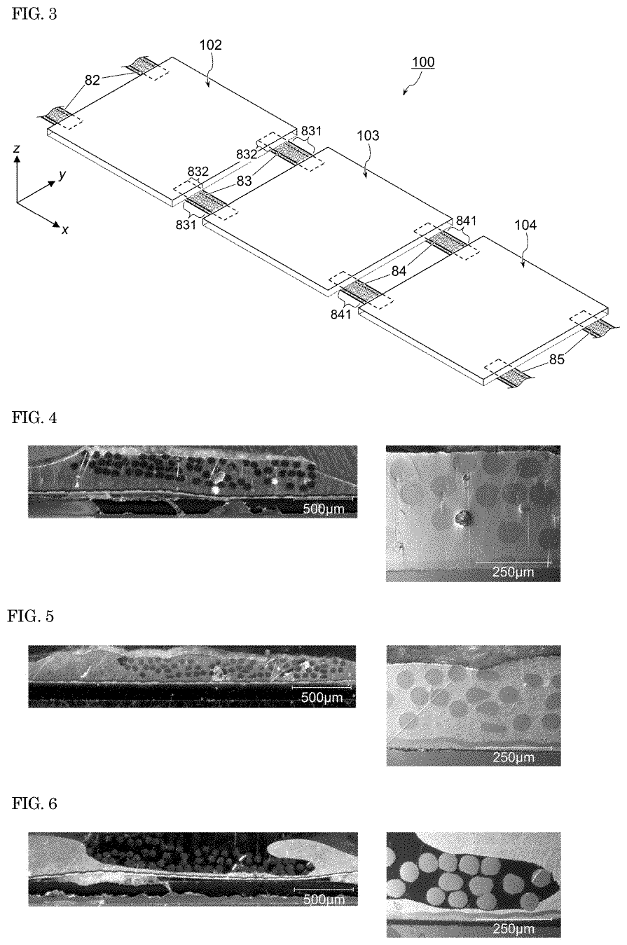

FIG. 3 is a schematic perspective view of the solar cell string 100 according to some embodiments.

Referring to FIG. 3, adjacent cells are connected by two wiring members. In some embodiments, the number of wiring members arranged between adjacent cells is appropriately set according to the shape of the electrode pattern of the cell or the like.

### Wiring Member

According to some embodiments, in the module, a braided wire having a flat-shaped cross-section and composed of a plurality of metal element wires is used as a wiring member which connects adjacent cells.

In some embodiments, a width of the wiring member ranges from about 1 mm to about 5 mm.

In some embodiments, a thickness of the wiring member ranges from about 30 μm to about 500 μm. In some embodiments, the thickness of the wiring member ranges from 50 μm to 300 μm. When the thickness of the wiring member ranges from 50 μm to 300 μm, the solder is able to permeate through the entire braided wire in a thickness direction so that the electroconductivity is secured, and an adhesiveness between the wiring member and the electrode is enhanced.

In some embodiments, the wiring member has a flat shape in which a width is large in comparison to a thickness. According to these embodiments, the contact area between the cell and the wiring member are increased, which results in the contact resistance. The increased contact area between the cell and the wiring member also improves the bonding reliability between the cell and the wiring member, leading to improvement of the durability of the solar cell module.

In some embodiments, the wiring member includes a braided wire. When the contact area between a general flat square wiring member to be for a general module and the cell increases, a connection failure such as peeling of the wiring member easily occurs due to a difference in linear expansion coefficient between the wiring member and the cell which is caused by a temperature change. On the other hand, a braided wire composed of a plurality of element wires is flexible and stretchable, so that stress caused by a difference in linear expansion due to a temperature change is absorbed and scattered by the wiring member. Therefore, according to these embodiments, even when the contact area between the cell and the wiring member is increased, high bonding reliability is able to be maintained.

In some embodiments, the braided wire having a flat-shaped cross-section is formed by knitting a plurality of metal element wires in such a manner as to form a flat shape. In some embodiments, the braided wire is formed by knitting a plurality of element wires into a cylindrical shape followed by making into the flat-shaped cross-section by, for example, a rolling processing. The method for knitting metal element wires is not particularly limited.

In some embodiments, the braided wire is a plain-knitted wire. In some embodiments, the plain-knitted wire includes a plurality of bundled wires. In some embodiments, the bundled wires include a plurality of element wires bundled together. In some embodiments, each bundled wire includes 3 to 50 element wires.

According to some embodiments, in the plain-knitted wire, each element wire is knitted so as to be exposed to the surface. When each element wire is exposed to the surface in the plain-knitted wire, a large number of contact points between the element wire and the electrode of the solar cell is established. As such, reliable electrical connection is able to be established. According to some embodiments, the plain-knitted wire conforms to JSC (Japanese Cable Makers' Association Standard) 1236, or other similar standards.

In some embodiments, the number of element wires present in one bundled wire is 10 or less. When the number of element wires in one bundle is 10 or less, solder is able to permeate between the element wires with ease. In some embodiments, the plain-knitted wire is obtained by knitting about 10 to about 50 bundled wires. In some embodiments, the number of element wires that constitute the plain-knitted wire ranges from about 30 to about 500.

The material forming the element wire is not particularly limited as long as the material electroconductive. In some embodiment, the material is a metal material and the metallic element wires are metallic element wires. In some embodiments, the metallic material constituting the metal element wire of the braided wire has a low resistivity, thereby reducing an electrical loss caused by resistance of the wiring member. In some embodiment, the material forming the element wire is copper, a copper alloy containing copper as a main component, aluminum, or an aluminum alloy containing aluminum as a main component. Copper and copper alloys are in general more conductive but more expensive. Aluminum and aluminum alloy are, in general, slightly less conductive than Copper or copper alloys but less expensive. In some embodiments, the surface of the element wire is covered by a tin plating, a silver plating, or the like.

In some embodiments, the metal electrode of the solar cell is a silver electrode. According to these embodiments, when a braided wire formed of copper element wires without surfaces coating is used as the wiring member for connecting the metal electrode of the solar cell, heating in modularization sometimes causes solder erosion, leading to reduction of connection strength. Therefore, in some embodiments, the wiring member connected to the silver electrode is a braided wire composed of a surface coated copper wire. In some embodiments, the metal element wires are copper or copper alloy element wires having a silver coating layer on the surface therefore. Because solder connection strength to the silver electrode is high, solder erosion caused by heating is suppressed by using the silver coated copper or copper alloy element wires.

In some embodiments, the element wires are subjected to blackening treatment. When the element wires are subjected to blackening treatment, the braided wire as a wiring member turns black, so that metal reflection is reduced, and therefore the wiring member and the back contact cell are uniformly colored black, leading to improvement of visuality of the solar cell module. In some embodiments, the plating or the blackening treatment is performed after element wires are knitted to form a braided wire.

In some embodiments, the wiring member used for connection adjacent cells is obtained by cutting a long braided wire to a predetermined length. In some embodiments, the length of the wiring member is the sum of about two times the length of a connection region between the cell and the wiring member in the x direction and the distance between adjacent cells. In the double-sided electrode type cell, generally the connection region between the cell and the wiring member extends from one end portion of the cell in the x direction to the vicinity of the other end portion. In the back contact cell, the wiring member is connected to only one end portion of the cell so that the n-side electrode and the p-side electrode are not short-circuited by the wiring member (see FIG. 3). Thus, in some embodiments, the length of the connection region between the cell and the wiring member in the x direction is about 2 mm to about 15 mm. When the length of the connection region between the cell and the wiring member in the x direction is excessively small, the connection area is insufficient, resulting in reduction of bonding strength and electrical loss.

When the braided wire is cut, the knitting in the vicinity of the cut surface is easily loosened. In the double-sided electrode type cell, loosening of the braided wire in the vicinity of the cut surface does not raise a significant problem because the connection length between the cell and the wiring member is large, whereas in the back contact cell, solder connection between the wiring member and the cell is sometimes difficult or electrical connection is sometimes insufficient when the end portion is loosened. Therefore, in some embodiments, a knitting pitch of the braided wire is 10 mm or less, for example 5 mm or less, 3 mm or less, or 2 mm or less. When the knitting pitch of the braided wire is in the above ranges, the amount of loosening of the knitting in the vicinity of the cut surface is reduced.

### Connection of Cell to Wiring Member

In some embodiments, adjacent cells are connected to each other through a wiring member to prepare a solar cell string. In some embodiments, the electrode of the cell is connected to the wiring member by solder. In some embodiments, a solder material permeates into the braided wire, so that voids between a plurality of metal element wires that constitute the braided wire are filled with solder. In some embodiments, the connection is one between a general flat square wiring member and a cell, and the wiring member is bonded to the cell with solder deposited on the surface of the wiring member. In some embodiments, the wiring member includes a braided wire, and voids between metal element wires are filled with a solder material. As such, the bonding reliability between the cell and the wiring member is improved.

Studies by the present inventors have revealed that mere application of heat with solder disposed on the surface of the braided wire does not allow a solder material to permeate into the braided wire, and connection strength between the wiring member and the cell is insufficient. In particular, refer to FIG. 3, in the back contact cell, the area of the connection region 832 between the cell and the wiring member is small, and therefore peeling of the wiring member due to insufficient bonding strength between the wiring member and the cell occurs easily.

Therefore, in some embodiments, voids between metal element wires are filled with a solder material that permeates into the braided wire. According to these embodiments, bonding strength between the cell and the braided wire are enhanced.

The method for permeating the solder material to into the braided wire is not particularly limited. In some embodiment, permeating the solder material to into the braided wire includes using a solder flux. In some embodiments, the solder flux is permeated into the braided wire before solder connection. According to these embodiments molten solder easily permeates into the braided wire. In some embodiments, preliminary solder is provided on the metal electrode of the cell, a braided wire as a wiring member is disposed on the solder, and a flux is applied from above the braided wire to allow the flux to permeate into the braided wire. In some embodiments, heat is applied from above the braided wire, so that the molten solder material permeates into voids between metal element wires due to capillary action. In some embodiments, during heating, additional solder is applied to allow the molten solder material to permeate into the braided wire from the upper surface of the braided wire. In some embodiments, a solder paste containing solder powder and flux is used. According to these embodiments, molten solder easily penetrates into the inside of the braided wire. In some embodiments, connecting the electrode of the cell and the wiring member using a solder paste includes applying the solder paste onto the metal electrode of the cell, disposing the braided wire as a wiring member on the solder paste, and applying heat from above the braided wire. According to these embodiments, flux exuded from the solder paste by heating permeates into the braided wire due to capillary action and, as such, the molten solder material easily permeates into voids between metal element wires.

According to some embodiments, in a cross-section (y-z plane) of the connection portion between the cell and the wiring member in a direction orthogonal to the extending direction of the wiring member, a ratio between an area filled with the solder material and a total area of the wiring member (area surrounded by element wires disposed on the outer periphery) ranges from 10% to 90%, such as 20% to 85%, such as 25% to 80%. According to some embodiments, in the y-z cross-section, the ratio between an area of the element wires and the total area of the wiring member ranges from 10% to 90%, 15% to 80%, or 20% to 75%. When the ratios are in the above-described ranges, desirable adhesiveness and electroconductivity are achieved.

According to some embodiments, in the y-z cross-section, the ratio of an area of voids and the total area of the wiring member is 30% or less, such as 10% or less, such as 5% or less, such as 1% or less, such as 0%. When the ratio is 0%, all the voids (voids between metal element wires) in the wiring member are filled with the solder material, adhesiveness and electroconductivity are improved.

As described above, the braided wire is easily loosened in the vicinity of the cut surface. Therefore, according to some embodiments, evaluation of the cross-section of the wiring member after solder connection is performed on the cross-section at a location separated by two or more pitches from the cut surface. When the connection length between the cell and the wiring member is less than 2 pitches, evaluation is performed on a cross-section at a position farthest from the cut surface of the connection region.

According to the embodiments above, because the wiring member formed of a braided wire is flexible and stretchable, the wiring member is adaptable to alignment in a string connection direction (x direction). Furthermore, because the wiring member including a braided wire that is able to bent in cell thickness direction (z direction), stress in the thickness direction is scattered. As such, even when the cell is warped, defects such as breakage at the time of handling a string after connection of a plurality of cells are suppressed.

In some embodiments, the cell is a back contact cell. In some embodiments, a solder connection pad is disposed in a portion of the cell end portion where finger electrodes are gathered, with the wiring member connected onto the solder connection pad. Since the braided wire composed of a plurality of element wires that is flexible and stretchable, the wiring member can be positioned on the solder connection pad by bending the wiring member. Thus, the area of the solder connection pad is be reduced.

In some embodiments, the cell is a double-sided electrode type cell. In some embodiments, a wiring member only needs to be connected to each of the electrode provided on the light-receiving surface of the cell and the electrode provided on the back surface. In a general double-sided electrode type cell, a grid-shaped pattern electrode consisting of a plurality of finger electrodes and bus bar electrodes orthogonal to the finger electrodes is provided on the light-receiving surface, and the wiring member is connected over substantially the entire length of the bus bar electrode.

### Modularization

Refer to FIG. 1, in the solar cell module 200, the solar cell string formed by a plurality of cells 102-104 connected by the wiring members 83 and 84 is sandwiched between a light-receiving-surface protection member 91 and a back-surface protection member 92. An encapsulant 95 is interposed between each of the protection members 91 and 91, as well as the solar cell string.

In some embodiments, a laminate in which the light-receiving-side encapsulant, the solar cell string, the back-side encapsulant and the back-surface protection member are mounted in this order on the light-receiving-surface protection member is heated at predetermined conditions to cure the encapsulant, thereby encapsulating the solar cell string. In some embodiments, before encapsulation, a plurality of solar cell strings are connected to form a solar cell grid, such as a solar cell grid as shown in FIG. 2.

In some embodiments, the encapsulant 95 includes a transparent resin. Examples of the transparent resin includes a polyethylene-based resin composition mainly composed of an olefin-based elastomer, polypropylene, an ethylene/α-olefin copolymer, an ethylene/vinyl acetate copolymer (EVA), an ethylene/vinyl acetate/triallyl isocyanurate (EVAT), polyvinyl butyrate (PVB), silicon, urethane, acrylic, epoxy, or combinations thereof. In some embodiments, the materials of the encapsulants on the light-receiving side and the back side are the same. In some embodiments, the materials of the encapsulants on the light-receiving side and the back side are different.

In some embodiments, the light-receiving-surface protection member 91 is light-transmissive. In some embodiments, the light-receiving-surface protection member 91 includes glass, transparent plastic or the like.

In some embodiments, the back-surface protection member 92 is light-transmissive, light-absorptive and light-reflective. Examples of the light-reflective back-surface protection member includes those having a metallic color or white color. In some embodiments, the back-surface protection member 92 includes a white resin film, a laminate with a metal foil of aluminum etc. sandwiched between resin films, or the like.

In some embodiments, the light-absorptive protection member includes a black resin layer having a black appearance. When a black sheet is used as the back-surface protection member in a module including back contact cells, the back-surface protection member is similar in appearance color to the cell, and therefore gaps between separately arranged cells are inconspicuous, so that a module having a high visuality is obtained. Further, when a braided wire subjected to blackening treatment is used as a wiring member, not only the back contact cell but also the wiring member and the back surface protection member exposed between adjacent cells are uniformly colored black, so that a module is obtained which is uniformly colored black as a whole, and has high visuality.

### Method of Manufacturing a Solar Cell Module

In some embodiments, the instant specification is directed to a method of manufacturing a solar cell module. In some embodiments, the method of manufacturing a solar cell module is a method of manufacturing the solar cell module as described above.

In some embodiments, the method of manufacturing the solar cell module includes forming a wiring member. In some embodiments, the formation of the wiring member is the same as or similar to those as described above.

In some embodiments, the method of manufacturing the solar cell module includes preparing a solar cell. In some embodiments, the preparation of the solar cell is the same as or similar to those as described above.

In some embodiments, the method of manufacturing the solar cell module includes solder-connecting the solar cell to the wiring member to form a solar cell string. In some embodiments, solder-connecting the solar cell to the wiring member is the same as or similar to those as described above.

In some embodiments, the method of manufacturing the solar cell module includes stacking the solar cell string with some additional layers, and laminate the stacked layers. In some embodiments, the additional layers, the order of stacking or the manner of lamination is the same as or similar to those as described above.

### EXAMPLES

Examples and Comparative Examples will be described hereinbelow, but the instant specification is not limited thereto.

### Examples 1 and 2 and Comparative Example 1

### <Preparation of Back Contact Cell>

A back contact cell was prepared using a 160 μm-thick 6-inch n-type single-crystalline silicon substrate (semi-square type with a side length of 156 mm). As a metal electrode on the back surface, an Ag/Cu electrode including a silver paste electrode and a copper-plated electrode arranged thereon was formed in accordance with the following procedure.

A silver paste was screen-printed on each of the n-type semiconductor layer and the p-type semiconductor layer, and temporarily baked at 140° C. for about 20 minutes, and a 80 nm-thick silicon oxide layer having a refractive index of 1.7 was formed by plasma CVD. Heating during deposition caused degassing from the Ag paste electrode and a volume change of the paste electrode, leading to formation of crack-like openings in the silicon oxide layer deposited on the underlying layer. The substrate was immersed in an electrolytic copper plating bath, and copper was deposited on the Ag silver paste electrode through the openings of the silicon oxide layer to form a 20 μm-thick copper-plated electrode.

### Example 1

Plain-knitted tin-plated copper wire (width: about 2 mm, thickness: about 200 μm, knitting pitch: about 1 mm) obtained by plain-knitting 16 bundled wires (64 element wires) each obtained by bundling four element wires each being a tin-plated copper wire having a diameter of about 80 μm was prepared. The plane knitted wire was cut to 20 mm, and one end portion thereof was solder-connected onto an electrode of a back contact cell (connection length: about 4 mm). First, preliminary solder was provided on the electrode of the cell, a plain-knitted wire was disposed thereon, and flux was applied and allowed to permeate into the plain-knitted wire. Thereafter, additional soldering was performed using a soldering iron from above the plain-knitted wire. An optical microscope image and an SEM image of a cross-section of a soldered portion (distance from cross-section of net braided wire: about 3 mm) are shown in FIG. 4. All the voids in the plain-knitted wire were filled with the solder material, and the area ratio of regions filled with the solder material in the cross section of the plain-knitted wire was about 50%.

### Example 2

The above-described plain-knitted tin-plated copper wire was immersed in an electroless palladium plating solution containing 0.5 g/L of palladium (“OPC Black Copper” manufactured by Okuno Chemical Industries Co., Ltd.), so that electroless plating was performed at room temperature to obtain a plain-knitted wire subjected to electroconductive blackening treatment at the entire surface. This blackened plain-knitted wire was solder-connected onto an electrode of a back contact cell in the same manner as in Example 1. An optical microscope image and an SEM image of a cross-section of a soldered portion are shown in FIG. 5. All the voids in the plain-knitted wire were filled with the solder material, and the area ratio of regions filled with the solder material in the cross section of the plain-knitted wire was about 72%.

### Comparative Example 1

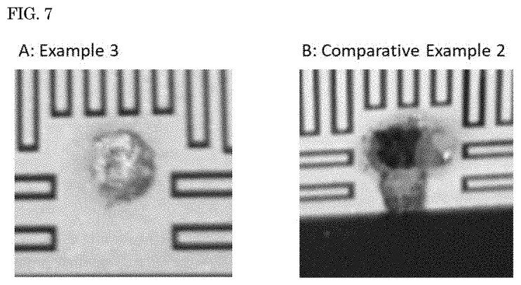

Preliminary solder was provided on an electrode of a cell, the plain-knitted tin-plated copper wire was disposed thereon, and without applying flux, additional soldering was performed from above the plain-knitted wire using a soldering iron. An optical microscope image and an SEM image of a cross-section of a soldered portion are shown in FIG. 6. Voids in the plain-knitted wire was not filled with a solder material.

Comparison between Examples 1 and 2 with Comparative Example 1 shows that when flux is allowed to permeate into the braided wire, connectivity between the metal electrode and the braided wire is improved by allowing the solder material to permeate into voids between metal element wires.

### Example 3 and Comparative Example 2

### <Preparation of Back Contact Cell>

A back contact cell was prepared using a 160 μm-thick 6-inch n-type single-crystalline silicon substrate (semi-square type with a side length of 156 mm). The silver paste was applied by screen printing, and heated at 180° C. for 60 minutes to form a 30 μm-thick silver electrode.

### Example 3

Plain-knitted silver-plated copper wire (width: about 2 mm, thickness: about 200 μm, knitting pitch: about 1 mm) obtained by plain-knitting 16 bundled wires (64 element wires) each obtained by bundling four element wires each being a silver-plated copper wire having a diameter of about 80 μm was prepared. The plane knitted wire was cut to 20 mm, and one end portion thereof was solder-connected onto a silver electrode of a back contact cell in the same manner as in Example 1.

### Comparative Example 2

Using a plain-knitted copper wire including non-plated copper wires as element wires, an end portion of a plain-knitted copper wire was solder-connected onto a silver electrode of a back contact cell in the same manner as in Example 3.

### <Evaluation of Bonding Strength>

Using a tensile tester, the plain-knitted wire was peeled off from the back contact cell under the condition of a tension speed of 0.8 mm/sec and an angle of 90° to measure the bonding strength (peeling strength). The bonding strength of a sample heated in an oven at 150° C. for 10 minutes was measured in the same manner as described above. A microscope photograph of the cell surface of the heated sample after measurement of the bonding strength (after peeling of the plain-knitted wire) is shown in FIG. 7.

### <Evaluation of Characteristics of Mini Module>

A plain-knitted wire was solder-connected to each of an n-side silver electrode and a p-side silver electrode of a back contact cell in the same manner as in Example 3 and Comparative Example 2, and the power was measured by a solar simulator. Thereafter, a back sheet, an EVA encapsulant, a back contact cell connected to a plain-knitted wire, an EVA encapsulant and glass were stacked in this order, and heated in a vacuum heat laminator at 150° C. for about 30 minutes to subject EVA to crosslinking reaction, thereby performing encapsulation. The power of the encapsulated mini module was measured by a solar simulator, and the current Isc before and after encapsulation, the open circuit voltage Voc, the fill factor FF, and the change ratio of the maximum power Pmax (after encapsulation/before encapsulation) were determined.

### <Evaluation Results>

The bonding strength between the wiring member (plain-knitted wire) and the silver electrode and the characteristic change ratio before and after encapsulation in the solar cell modules of Example 3 and Comparative Example 2 are shown in Table 1.

TABLE 1

| | Bonding strength | | Photo- | Characteristic change | | | |
|---|---|---|---|---|---|---|---|
| | (N/2 mm) | | graphs | (after encapsulation/ | | | |
| | Before | After | after | before encapsulation) | | | |
| | heating | heating | peeling | Isc | Voc | FF | Pmax |
| Example 3 | 0.4 | 0.4 | FIG. 7A | 1.002 | 1.001 | 1.003 | 1.006 |
| Comparative | 0.3 | 0.0 | FIG. 7B | 1.000 | 1.003 | 0.877 | 0.880 |
| Example 2 | | | | | | | |

In Comparative Example 2 where a braided wire (wiring member) consisting of uncoated copper element wire was used, the bonding strength of the wiring member after heating at 150° C. was zero (substantially not bonded), and solder was not deposited on the surface of the cell after peeling of the wiring member (FIG. 7B). In addition, in the mini module encapsulated at 150° C., the fill factor was significantly reduced as compared to that before encapsulation. These results indicate that in Comparative Example 2, the silver electrode of the cell was appropriately connected to the wiring member immediately after solder connection, but heating in encapsulation caused solder erosion, so that adhesion between the electrode and the wiring member was reduced, leading to reduction of the fill factor.

On the other hand, in Example 3 where a braided wire consisting of silver-coated copper element wire was used, the bonding strength was not changed before and after heating at 150° C., and the mini module after encapsulation exhibited characteristics equal to or higher than those before encapsulation. In addition, the solder remained on the surface of the cell after peeling of the wiring member (FIG. 7A), the solder was deposited on the surface of the wiring member after peeling, and solder erosion did not occur.

These results reveal that by using a braided wire consisting of silver-covered copper element wire, solder erosion at a solder-bonded portion to a silver electrode is suppressed, and a solar cell module with a high power and excellent adhesion between an electrode and a wiring member are obtained.

### DESCRIPTION OF REFERENCE SIGNS

101 to 105 solar cell (cell)
81 to 86 wiring member (braided wire)
832 connection region
100, 110, 120 solar cell string
91 light-receiving-surface protection member
92 back-surface protection member
95 encapsulant
200 solar cell module

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A solar cell module comprising at least one solar cell string, wherein the solar cell string comprises:
a plurality of solar cells, wherein
each of the plurality of solar cells comprises a metal electrode on at least one of a light-receiving surface or a back surface thereof; and
at least one wiring member electrically connecting the plurality of solar cells together, wherein
the wiring member is a braided wire having a flat-shaped cross-section and comprises a plurality of metal element wires, and
the metal electrode of each of the plurality of solar cells is connected to the wiring member by solder.

2. The solar cell module according to claim 1, wherein voids between adjacent metal elements wires of the plurality of metal element wires in the braided wire are filled with a solder material.

3. The solar cell module according to claim 2, wherein in a cross-section of the wiring member, an area filled with the solder material ranges from 10% to 90% based on a total area of the at least one wiring member.

4. The solar cell module according to claim 2, wherein in a cross-section of the wiring member, an area of voids where neither metal element wire nor the solder material presents is 30% or less based on a total area of the at least one wiring member.

5. The solar cell module according to claim 1, wherein the at least one wiring member is a plain-knitted wire, and comprises a plurality of bundles of the metal element wires.

6. The solar cell module according to claim 5, wherein a number of metal element wires in one bundled wire is 10 or less.

7. The solar cell module according to claim 1, wherein each of the plurality of metal element wires are copper wires or copper alloy wires.

8. The solar cell module according to claim 1, wherein each of the plurality of metal element wires are copper wires or copper alloy wires having a silver or tin coating on a surface thereof.

9. The solar cell module according to claim 1, wherein
each of the plurality of the metal element wires are copper wires or copper alloy wires having a silver coating on a surface thereof, and
the metal electrode of the solar cell is a silver electrode.

10. The solar cell module according to claim 1, wherein
the solar cell is a back contact solar cell having no metal electrode on the light-receiving surface and having metal electrodes only on the back surface, and
in the solar cell string, back surfaces of adjacent solar cells are connected to each other through the wiring member.

11. A method of producing the solar cell module claim 1, comprising:
solder-connecting each of the plurality of solar cells to the at least one wiring member to form the solar cell string, comprising permeating a solder material from an outer periphery of the braided wire into voids between the plurality of metal element wires of braided wire.

12. The method of claim 11, wherein solder-connecting the solar cell to the wiring member further comprises permeating a solder flux into the braided wire.

13. The method of claim 12, wherein solder-connecting the solar cell comprises:
providing a preliminary solder on the metal electrode of the cell;
placing the metal electrode against the braided wire so that preliminary solder material is on a first side of the braided wire;
placing the solder flux on a second side of the braided wire so as to allow the solder flux to permeate into the braided wire; and
applying heat from the second side so that the molten solder material permeates into voids between metal element wires.

14. The method of claim 13, wherein solder-connecting the solar cell further comprises, before or during applying heat,
applying an additional solder material from the second side of the braided wire.

15. The method of claim 12, wherein solder-connecting the solar cell comprises:
applying a mixture of the solder material and the solder flux on the metal electrode of the cell; and
placing the braided wire against the mixture; and
applying heat to the mixture and the braided wire.

16. The method of claim 11, further comprises forming the wiring member, wherein forming the wiring member comprises:
bundling a plurality of the metal element wires into a bundled wire;
knitting a plurality of the bundled wires to form the braided wire.

17. The method of claim 16, wherein knitting a plurality of the bundled wires comprises a plan-knitting.

18. The method of claim 16, wherein forming the wiring member further comprises cutting the braided wire into a predetermined length.

19. The method of claim 16, wherein forming the wiring member further comprises performing a plating or a blackening treatment on the braided wire.

20. The method of claim 11, further comprises:
stacking a light-receiving-surface protection member, a light-receiving-side encapsulant, the solar cell string, a back-side encapsulant and a back-surface protection member in this order; and
laminating the light-receiving-surface protection member, the light-receiving-side encapsulant, the solar cell string, the back-side encapsulant and the back-surface protection member.
